(19) United States
(12) Patent Application Publication
(10) Pub. No.: US 2024/0258178 A1
(43) Pub. Date: Aug. 1, 2024

(54) METHOD OF DETECTING OVERLAY OF PATTERNS AND METHOD OF FORMING PATTERNS USING THE SAME

(71) Applicant: SAMSUNG ELECTRONICS CO., LTD., Suwon-si (KR)

(72) Inventors: Minsu LEE, Suwon-si, Gyeonggi-do (KR); Minsu KANG, Suwon-si, Gyeonggi-do (KR); Sangho YUN, Suwon-si, Gyeonggi-do (KR); Chan HWANG, Suwon-si, Gyeonggi-do (KR)

(21) Appl. No.: 18/396,878

(22) Filed: Dec. 27, 2023

(30) Foreign Application Priority Data
Jan. 30, 2023 (KR) 10-2023-0011501

(51) Int. Cl. H01L 21/66

(52) U.S. Cl. CPC H01L 22/12

(57) ABSTRACT

A method of detecting overlay of patterns includes forming a lower pattern and an upper pattern on a substrate. A sample pattern is drawn that has a common tangential line with the lower pattern. A position of a real center of gravity of the lower pattern is calculated using the common tangential line.

### CROSS-REFERENCE TO RELATED APPLICATION

This application claims priority under 35 U.S.C. § 119 to Korean Patent Application No. 10-2023-0011501, filed on Jan. 30, 2023 in the Korean Intellectual Property Office, the disclosure of which is incorporated by reference in its entirety herein.

### 1. TECHNICAL FIELD

Embodiments of the present disclosure relate to a method of detecting overlay of patterns and method of forming patterns using the same.

### 2. DISCUSSION OF RELATED ART

Patterns are formed on a substrate at a plurality of levels. The patterns that are formed on the substrate at various different levels need to be aligned with each other. For example, a lower pattern is formed on the substrate and an upper pattern is formed on the lower pattern. To determine whether the lower and upper patterns are properly aligned, an overlay between a central position of the lower pattern and a central position of the upper pattern is detected.

However, the lower pattern may be partially hidden by the upper pattern, and for example, a center of gravity may be detected based on a portion of the lower pattern that is not hidden by the upper pattern. Therefore, accurately detecting a central position of the lower pattern may be difficult.

### SUMMARY

Embodiments of the present disclosure provide a method of detecting overlay of patterns.

Embodiments of the present disclosure provide a method of forming patterns using the method of detecting overlay of patterns.

According to an embodiment of the present inventive concept, a method of detecting overlay of patterns includes forming a lower pattern and an upper pattern on a substrate. A sample pattern is drawn that has a common tangential line with the lower pattern. A position of a real center of gravity of the lower pattern is calculated using the common tangential line.

According to an embodiment of the present inventive concept, a method of detecting overlay of patterns includes forming a lower pattern and an upper pattern on a substrate. A determination is made whether the lower pattern is within a region in where the lower pattern is hidden by the upper pattern. A sample pattern is drawn that has a common contact point with the lower pattern. A common tangential line of the lower pattern and the sample pattern is determined at the common contact point. A position of a real center of gravity of the lower pattern is calculated using the common tangential line. A position of a center of the upper pattern is compared with the position of the calculated real center of gravity of the lower pattern.

According to an embodiment of the present inventive concept, a method of forming patterns includes forming a first lower pattern and a first upper pattern on a substrate. A sample pattern is drawn that has a common tangential line with the first lower pattern. A position of a real center of gravity of the first lower pattern is calculated using the common tangential line. A position of a center of the first upper pattern is compared with the position of the calculated real center of gravity of the first lower pattern to detect an error of overlay of the first lower pattern and the first upper pattern. A second lower pattern and a second upper pattern is formed on the substrate by reflecting the error of overlay of the first lower pattern and the first upper pattern.

In the method of detecting overlay of patterns, even if the lower pattern is formed in a region where the lower pattern is hidden by the upper pattern, the position of the center of the lower pattern may be accurately determined, and thus the overlay between the upper pattern and the lower pattern may be accurately detected. Additionally, the upper and lower patterns may be formed to be sufficiently aligned with each other by reflecting the error of overlay.

### BRIEF DESCRIPTION OF THE DRAWINGS

FIG. 1 is a flowchart illustrating a method of detecting overlay of patterns according to an embodiment of the present inventive concept.

FIGS. 2 to 5 are plan views illustrating a method of detecting the overlay of patterns according to embodiments of the present inventive concept.

FIGS. 6 and 7 are plan views illustrating a method of detecting overlay of patterns according to embodiments of the present inventive concept.

### DETAILED DESCRIPTION OF EMBODIMENTS

The above and other aspects and features of a gate structure and a method of forming the same, and a semiconductor device including the gate structure and a method of manufacturing the same in accordance with non-limiting embodiments will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from embodiments of the present inventive concept.

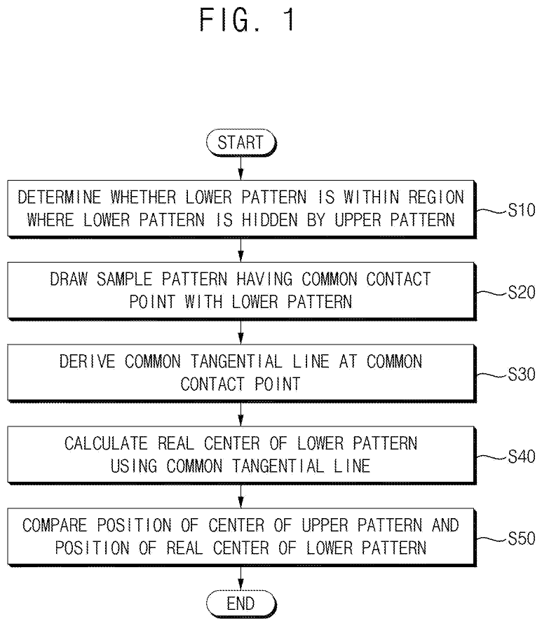

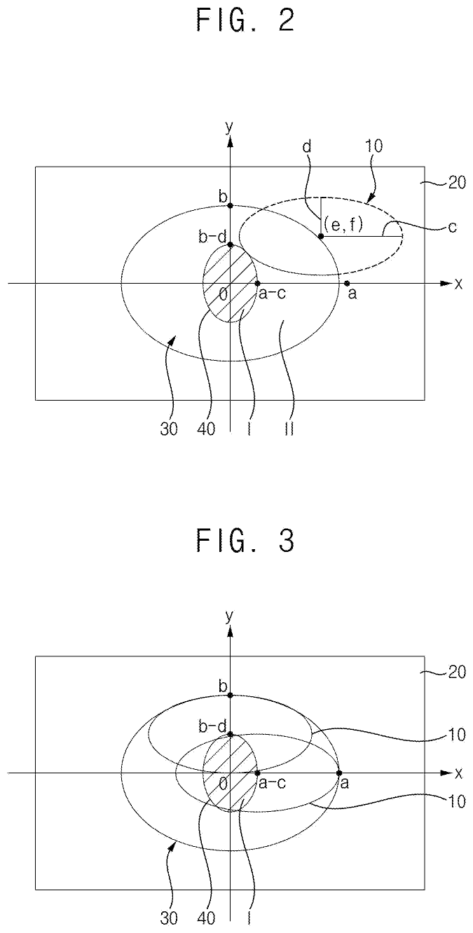

FIG. 1 is a flowchart illustrating a method of detecting overlay of patterns, and FIGS. 2 to 5 are plan views illustrating a method of detecting the overlay of patterns.

Referring to FIGS. 1 and 2, in step S10, it is determined whether a lower pattern 10 is within a region in which at least a portion of the lower pattern 10 may be hidden by an upper pattern 20.

The lower pattern 10 may be formed on a substrate. In an embodiment, the substrate may include silicon, germanium, silicon-germanium, or a III-V group compound semiconductor, such as GaP, GaAs, or GaSb. For example, in an embodiment, the substrate may be a silicon-on-insulator (SOI) substrate or a germanium-on-insulator (GOI) substrate. However, embodiments of the present inventive concept are not necessarily limited thereto.

In an embodiment as shown in FIG. 2, the lower pattern 10 may have a shape of an ellipse in a plan view, and hereinafter, a contour of the lower pattern 10 in a plan view is defined as a first ellipse. However, embodiments of the present inventive concept are not necessarily limited thereto and the shape of the lower pattern 10 may vary.

In an embodiment, the lower pattern 10 may include a conductive material, such as a metal, a semiconductor material, such as polysilicon, or an insulating material, such as an oxide, a nitride, etc.

The upper pattern 20 may be formed on the lower pattern 10. The upper pattern 20 may include an opening 30 at least partially exposing an upper surface of the lower pattern 10. In an embodiment, the opening 30 may have a shape of an ellipse in a plan view, and hereinafter, a contour of the opening 30 in a plan view may be defined as a second ellipse. However, embodiments of the present inventive concept are not necessarily limited thereto and the shape of the opening 30 may vary.

The upper pattern 20 may include an insulating material, such as an oxide, a nitride, etc., a semiconductor material, such as polysilicon, or a conductive material, such as a metal.

The second ellipse may have a major axis and a minor axis of which lengths are “a” and “b,” respectively, and a center of the second ellipse may be located at an origin of a orthogonal coordinate system. Additionally, the first ellipse may have a major axis and a minor axis of which lengths are “c” and “d,” respectively, and a center of the first ellipse may be located at (e, f) of the orthogonal coordinate system.

The “a” and the “b” of the respective lengths of the major and minor axes of the second ellipse may be detected, and the “c” and the “d” of the respective lengths of the major and minor axes of the first ellipse may be detected, or calculated or estimated.

A difference between the lengths of the major axes of the first and second ellipses is “a−c,” and a difference between the lengths of the minor axes of the first and second ellipses is “b−d,” and thus, if the center of the first ellipse is located in an inside of a first region I defined by a third ellipse 40 of which lengths of major and minor axes are “a−c” and “b−d” and of which a center is located at the origin of the orthogonal coordinate system, the lower pattern 10 may be entirely exposed by the opening 30. Accordingly, the first region I may be a region in which the lower pattern 10 is not hidden by the upper pattern 20 if the center of the lower pattern 10 is disposed within the first region I. For example, if the center of the lower pattern 10 is located within the first region I, the lower pattern 10 may not be hidden by the upper pattern 20, and the “c” and the “d” that are the lengths of the major and minor axes, respectively, may be detected.

For example, when a center of gravity of the lower pattern 10 is detected within the first region I, the lower pattern 10 is not hidden by the upper pattern 20 but may be entirely exposed by the opening 30, so that the detected center of gravity of the lower pattern 10 may be the same as a real center of gravity of the lower pattern 10.

Accordingly, the overlay of the lower pattern 10 and the upper pattern 20 may be detected based on a center of the opening 30, such as the origin of the orthogonal coordinate system and the center of gravity of the lower pattern 10, and an additional process for detecting the overlay of the lower and upper patterns 10 and 20 does not need to be performed.

However, if the center of gravity is located outside of the first region I, such as inside of a second region II, the lower pattern 10 may not be entirely exposed by the opening 30 but may only be partially exposed. Thus, the second region II may be a region in which a portion of the lower pattern 10 is hidden by the upper pattern 20. If the center of gravity of the lower pattern 10 is located within the second region II, the lower pattern 10 may be at least partially hidden by the upper pattern 20, and the “c” and the “d” that are the lengths of the major and minor axes, respectively, may be calculated or approximately estimated based on data of a contour of a portion of the lower pattern 10 exposed by the opening 30.

For example, when the center of gravity of the lower pattern 10 is detected when the real center of gravity is located outside of the first region I, the lower pattern 10 is partially hidden by the upper pattern 20, and thus only a portion of the center of gravity of the lower pattern 10 exposed by the opening 30 may be detected. Therefore, the detected center of gravity of the lower pattern 10 may not be the same as a real center of gravity of the lower pattern 10.

Accordingly, the overlay of the lower pattern 10 and the upper pattern 20 may not be detected based on the center of the opening 30, such as the origin of the orthogonal coordinate system and the detected center of gravity of the lower pattern 10. Thus, the center of gravity of the exposed portion of the lower pattern 10 and a position of the real center of gravity of the lower pattern 10 may be calculated by a following method which permits the overlay to be estimated based on the origin of the orthogonal coordinate system and the calculated position of the real center of gravity of the lower pattern 10.

The third ellipse 40 may be represented by Equation 1, as follows:

$$\frac{{x}^{2}}{{( a - c )}^{2}} + \frac{{y}^{2}}{{( b - d )}^{2}} = 1 \qquad < Equation 1 >$$

When coordinates of the detected center of the portion of the lower pattern 10 exposed by the opening 30 are (x1, y1), if

$$\frac{x {1}^{2}}{{( a - c )}^{2}} + \frac{y {1}^{2}}{{( b - d )}^{2}} \leq 1 ,$$

the center of gravity of the lower pattern 10 is inside of the region I. Therefore, the real center of the first ellipse may be considered to be inside of the first region I. In this case, the detected center of gravity of the lower pattern 10 may be the same as the real center of gravity, and thus an additional process for detecting the overlay does not need to be performed and the overlay may be detected based solely on the coordinates of the detected center of gravity of the lower pattern 10.

### Alternatively, if

$$\frac{x {1}^{2}}{{( a - c )}^{2}} + \frac{y {1}^{2}}{{( b - d )}^{2}} > 1 ,$$

the real center of gravity of the lower pattern 10 is outside of the region I, so that the center of the first ellipse may be considered to be in the second region II. In this case, the detected center of gravity of the lower pattern 10 may not be the same as the real center of gravity, and thus an additional process for detecting the overlay is needed to be performed.

For example, a determination of whether the lower pattern 10 is within the region in which the lower pattern 10 is hidden by the upper pattern 20, such as within the second region II, may be made by evaluating whether the detected center of gravity of the portion of the lower pattern 10 exposed by the opening 30 satisfies the following Discriminant 1:

$$\frac{x {1}^{2}}{{( a - c )}^{2}} + \frac{y {1}^{2}}{{( b - d )}^{2}} > 1 . \qquad < Discriminant 1 >$$

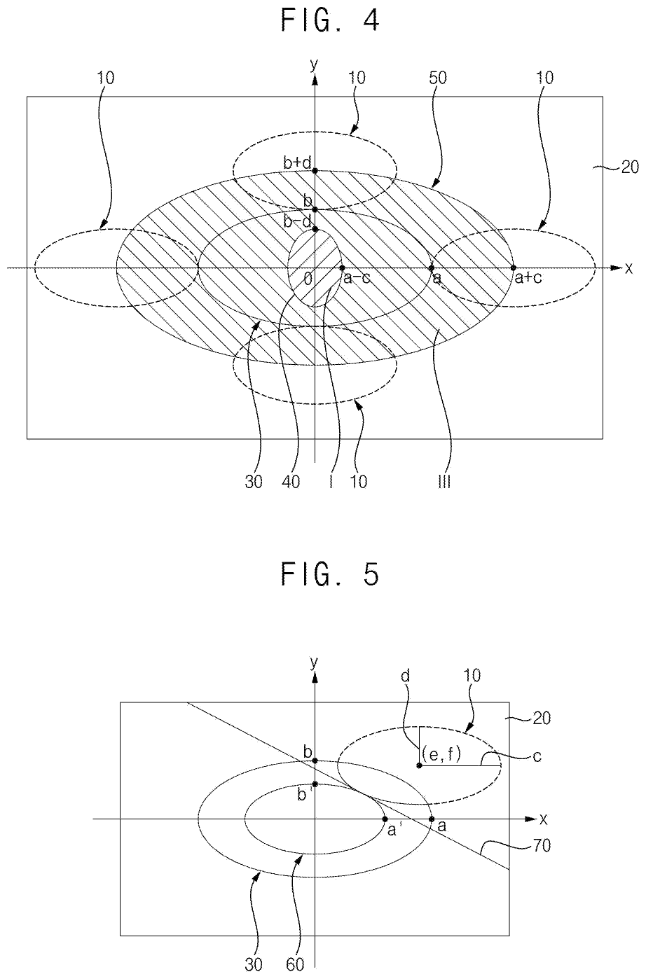

FIG. 3 is a plan view illustrating a maximum area of the first region in which a lower pattern is not hidden by an upper pattern, and FIG. 4 is a plan view illustrating a maximum area of a third region in the first region in which a position of a real center of gravity of the lower pattern may be calculated.

Referring to FIG. 3, if the real center of the first ellipse is inside of the first region I defined by the third ellipse 40, the lower pattern 10 may not be hidden by the upper pattern 20, so that the maximum area of the first region I may be an inner area of the third ellipse 40 having the lengths of the major and minor axes of “a−c” and “b−d,” respectively.

Referring to FIG. 4, when at least one point of the first ellipse is inside of the second ellipse, at least a portion of the lower pattern 10 may not be hidden by the upper pattern 20 so that the position of the real center of gravity of the lower pattern 10 may be calculated by a following method. Thus, the maximum area of a third region may be an inner area of a fourth ellipse 50 having lengths of major and minor axes of “a+c” and “b+d,” respectively.

For example, a third region III in which the lower pattern 10 is not entirely hidden but only partially hidden by the upper pattern 20 may have an area greater than an area of the first region I in which an entirety of the lower pattern 10 is not hidden by the upper pattern 20 when the center of gravity is disposed in the first region I. For example, in an embodiment, the third region III may be approximately thirteen times the first region I. However, embodiments of the present inventive concept are not necessarily limited thereto.

Referring to FIGS. 1 and 5, in step S20, if the lower pattern 10 is determined to be within the region in which the lower pattern 10 is hidden by the upper pattern 20, that is, within the second region II, a sample pattern having a common contact point with the lower pattern 10 may be drawn.

In an embodiment, a pattern with a contour of a fifth ellipse 60 having a shape similar to (e.g., symmetrical thereto) the second ellipse and a size that is smaller than the second ellipse may be drawn, and the size of the fifth ellipse 60 may increase until the fifth ellipse 60 directly contacts the first ellipse. Accordingly, the sample pattern having the common contact point with the lower pattern 10 may be drawn.

When lengths of major and minor axes of the fifth ellipse 60 are “a” and “b′,” the fifth ellipse 60 may be represented by Equation 2, as follows.

$$\frac{{x}^{2}}{{( {a}^{′} )}^{2}} + \frac{{y}^{2}}{{( {b}^{′} )}^{2}} = 1 \qquad < Equation 2 >$$

The fifth ellipse 60 has a shape that is similar to (e.g., symmetrical to) the second ellipse, and thus Formula 1 may be derived.

$$a / b = {a}^{′} / {b}^{′} \qquad < Formula 1 >$$

Additionally, when coordinates of the common contact point of the fifth ellipse 60 and the first ellipse are (p, q), Formula 2 may be derived.

$$\frac{{p}^{2}}{{( {a}^{′} )}^{2}} + \frac{{q}^{2}}{{( {b}^{′} )}^{2}} = 1$$

When the coordinates of the common contact point of the fifth ellipse 60 and the first ellipse, that is, (p, q) are detected, a′ and b′ may be calculated by Formula 1 and Formula 2. Accordingly, Equation 2 of the fifth ellipse 60 having the common contact point with the first ellipse at the coordinates (p, q) may be derived.

In step S30, an equation of a tangential line 70 contacting the fifth ellipse 60 at the common contact point may be derived.

The tangential line 70 may also directly contact the first ellipse, and thus may be referred to as a common tangential line.

The tangential line 70 may be represented by Equation 3, as follows.

$$y = mx + n \qquad < Equation 3 >$$

In Equation 2, if we differentiate both sides of Equation 2 with respect to x and substitute (p, q) for (x, y), Formula 3 may be derived.

$$\frac{dy}{dx} = - \frac{{p ( {b}^{′} )}^{2}}{{q ( {a}^{′} )}^{2}} \qquad < Formula 3 >$$

Additionally, Formula 4 may be derived.

$$m = - \frac{{p ( {b}^{′} )}^{2}}{{q ( {a}^{′} )}^{2}} \qquad < Formula 4 >$$

If we substitute (p, q) for (x, y) in Equation 3, then Formula 5 may be derived.

$$q = mp + n \qquad < Formula 5 >$$

From Formula 2, Formula 4 and Formula 5, Formula 6 may be derived.

$$n = \frac{{( {b}^{′} )}^{2}}{q} \qquad < Formula 6 >$$

Accordingly, the tangential line 70 may be represented as follows.

$$y = - \frac{{p ( {b}^{′} )}^{2}}{{q ( {a}^{′} )}^{2}} x + \frac{{( {b}^{′} )}^{2}}{q} \qquad < Equation 3 >$$

In step S40, the position of the center of the first ellipse may be calculated from Equation 3 of the tangential line 70, as follows.

The first ellipse may be represented by Equation 4, as follows.

$$\frac{{( x - e )}^{2}}{{c}^{2}} + \frac{{( y - f )}^{2}}{{d}^{2}} = 1 \qquad < Equation 4 >$$

If we substitute (p, q) for (x, y) in Equation 4, Formula 7 may be derived.

$$\frac{{( p - e )}^{2}}{{c}^{2}} + \frac{{( q - f )}^{2}}{{d}^{2}} = 1 \qquad < Formula 7 >$$

If we differentiate both sides of Equation 4 with respect to x and substitute (p, q) for (x, y), Formula 8 may be derived.

$$\frac{dy}{dx} = - \frac{{d}^{2}}{{c}^{2}} \frac{( p - e )}{( q - f )} \qquad < Formula 8 >$$

A slope m at the contact point (p, q) satisfies Formula 4, as follows.

$$m = - \frac{{p ( {b}^{′} )}^{2}}{{q ( {a}^{′} )}^{2}} \qquad < Formula 4 >$$

Thus, Formula 9 may be derived.

$$- \frac{{p ( {b}^{′} )}^{2}}{{q ( {a}^{′} )}^{2}} = - \frac{{d}^{2}}{{c}^{2}} \frac{( p - e )}{( q - r )} \qquad < Formula 9 >$$

Accordingly, from Formula 7 and Formula 9, coordinates “e” and “f” of the center of the first ellipse may be represented as follows.

$$e = p - \frac{{m ( {c}^{2} {m}^{2} + {d}^{2} )}^{0.5}}{\frac{{d}^{2}}{{c}^{2}} + {m}^{2}}$$

$$f = q \frac{\frac{{d}^{2}}{{c}^{2}} {( {c}^{2} {m}^{2} + {d}^{2} )}^{0.5}}{\frac{{d}^{2}}{{c}^{2}} + {m}^{2}}$$

(Herein,

$$m = - \frac{{p ( {b}^{′} )}^{2}}{{q ( {a}^{′} )}^{2}} )$$

In step S50, the overlay of the lower pattern 10 and the upper pattern 20 may be detected by a comparison between the position of the calculated center of the first ellipse and the position of the center of the upper pattern 20, such as the origin of the orthogonal coordinate system.

As illustrated above, whether the lower pattern 10 is within the region in which the lower pattern 10 is hidden by the upper pattern 20, such as within the second region II may be determined by the discriminant, and if the lower pattern 10 is determined within the second region II, then the sample pattern having the contour similar to the shape of the opening 30 included in the upper pattern 20 may be drawn and the size of the sample pattern may be increased until the sample pattern may have the common contact point with the lower pattern 10. The common tangential line may be derived (e.g., determined) at the common contact point, and the position of the real center of gravity of the lower pattern 10 may then be calculated.

The position of the real center of gravity of the lower pattern 10 and the position of the center of the opening 30 included in the upper pattern 20 may be compared to detect the overlay between the lower pattern 10 and the upper pattern 20.

After detecting the overlay of the patterns, an error of the overlay may be reflected when subsequent patterns are formed. For example, a second lower pattern and a second upper pattern may be formed on the substrate by reflecting the error of overlay of the first lower pattern and the first upper pattern.

Generally, patterns on a wafer may be formed by forming an etching object layer on the wafer, forming a photoresist layer on the etching object layer, patterning the photoresist layer to form a photoresist pattern, and etching the etching object layer using the photoresist pattern as an etching mask. An etching mask layer may be further formed between the etching object layer and the photoresist layer, and in this case, the etching mask layer may be etched using the photoresist pattern to form an etching mask, and the etching object layer may be etched using the etching mask.

In an embodiment, the formation of the photoresist pattern by patterning the photoresist layer may be performed by placing a photomask, such as a reticle on which a layout of a given pattern is drawn over the photoresist layer, performing an exposure process in which a light is emitted from a light source to penetrate through the photomask, and performing a developing process in which a portion of the photoresist layer exposed or unexposed by the light is removed, so that the layout of the given pattern may be transferred to the photoresist layer.

A photomask used in an exposure process may be manufactured by designing a layout of a pattern, for example, the lower pattern 10 or the upper pattern 20, performing an optical proximity correction (OPC) to correct the layout of the pattern, and forming the lower pattern 10 or the upper pattern 20 to have the corrected layout.

However, the lower pattern 10 and the upper pattern 20, which may be formed by the exposure process and a developing process, may not be sufficiently aligned with each other, and thus, if an overlay between the lower and upper patterns 10 and 20 is detected and an error is found, the error needs reflecting.

For example, when the layouts of the lower and upper patterns 10 and 20 are designed, the error of overlay may be reflected. Alternatively, when the exposure process is performed using the photomask including the lower and upper patterns 10 and 20, the direction of the exposure beam may be changed in reflection of the error of overlay. By reflection of the overlay error, the lower and upper patterns 10 and 20 may not be misaligned with each other, but may be sufficiently aligned with each other.

Each of the lower and upper patterns 10 and 20 may be various structures included in a semiconductor device, for example, wirings, vias, contact plugs of a wiring structure, or an insulating interlayer at least partially cover the wiring structure.

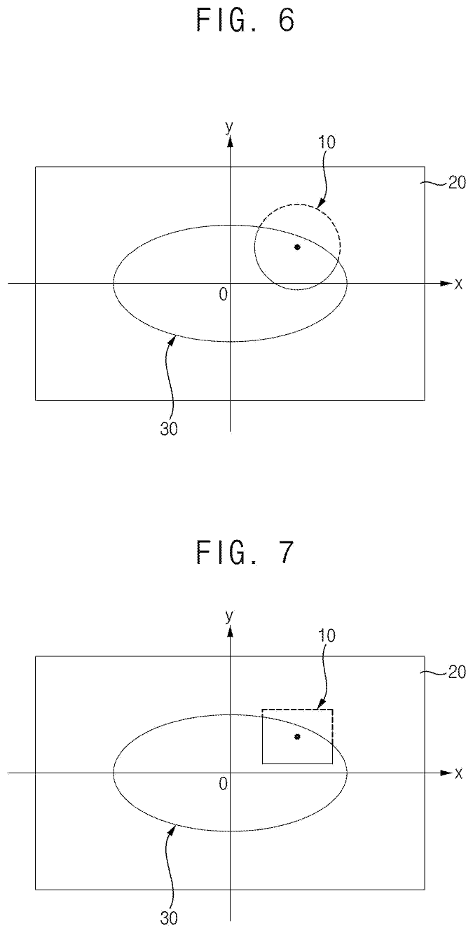

FIGS. 6 and 7 are plan views illustrating a method of detecting overlay of patterns.

This method may be substantially the same as the method illustrated with reference to FIGS. 1 to 5, except for the shape of the lower pattern, and thus repeated explanations may be omitted herein for economy of description.

Referring to FIG. 6, the lower pattern 10 may have a shape of a circle instead of an ellipse in a plan view.

The steps S10, S20, S30 and S40 may be performed to calculate the position of the real center of gravity of the lower pattern 10, and the sample pattern used in step S20 may have a shape of an ellipse similar to the second ellipse that is a contour of the opening 30 of the upper pattern 20.

A contour of the lower pattern 10 may have a shape of a circle, and when a center of the circle is located at an origin of an orthogonal coordinate system and a radius of the circle is “r,” the circle may be represented by Equation 5, as follows.

$${x}^{2} + {y}^{2} = {r}^{2} \qquad < Equation 5 >$$

In step S30, an equation of a common tangential line at a common contact point of the sample pattern and the circle may be derived, and in step S40, a position of a real center of the circle may be calculated from the derived equation of the common tangential line.

Referring to FIG. 7, the lower pattern 10 may have a shape of a rectangle instead of an ellipse in a plan view.

The steps S10, S20, S30 and S40 may be performed to calculate the position of the real center of gravity of the lower pattern 10, and the sample pattern used in step S20 may have a shape of an ellipse similar to the second ellipse that is a contour of the opening 30 of the upper pattern 20.

A contour of the lower pattern 10 may have a shape of a rectangle, and each of sides of the rectangle may be represented by Equation 6 or Equation 7, as follows.

$$x = s ( s is a constant ) \qquad < Equation 6 >$$

$$y = t ( t is a constant ) \qquad < Equation 7 >$$

In step S30, an equation of a common tangential line at a common contact point of the sample pattern and one of the sides of the rectangle may be derived, and in step S40, a position of a real center of the rectangle may be calculated from the derived equation of the common tangential line.

In an embodiment, the lower pattern 10 may have a shape of one of an ellipse, a circle and a rectangle. However, embodiments of the present inventive concept is not necessarily limited thereto. The opening 30 included in the upper pattern 20 may also have a shape of one of an ellipse, a circle, a rectangle, etc.

The method of detecting the overlay of patterns and the method of forming the patterns using the same may be applied to methods of manufacturing logic devices such as CPUs, MPUs, APs, etc., volatile memory devices such as SRAMs, DRAMs, etc., and non-volatile memory devices such as flash memory devices, PRAMs, MRAMs, RRAMs, etc.

For example, if various patterns of various structures, such as wiring structures, insulating interlayers included in each of the logic devices, volatile memory devices or non-volatile memory devices may be formed at a plurality of levels, respectively, and the overlay between lower and upper patterns of the various patterns is detected, embodiments of the present inventive concept may be applied thereto.

While the present inventive concepts have been shown and described with reference to non-limiting embodiments thereof, it will be understood by those of ordinary skill in the art that various changes in form and details may be made thereto without departing from the spirit and scope of the present inventive concept.

What is claimed is:

1. A method of detecting overlay of patterns, the method comprising:
forming a lower pattern and an upper pattern on a substrate;
drawing a sample pattern having a common tangential line with the lower pattern; and
calculating a position of a real center of gravity of the lower pattern using the common tangential line.

2. The method according to claim 1, wherein the upper pattern includes an opening at least partially exposing the lower pattern.

3. The method according to claim 2, further comprising:
prior to drawing the sample pattern having the common tangential line with the lower pattern, determining whether the lower pattern is within a region where the lower pattern is hidden by the upper pattern.

4. The method according to claim 3, wherein:
a contour of the lower pattern is a first ellipse having lengths of major and minor axes of c and d, respectively, in a plan view;
a contour of the opening of the upper pattern is a second ellipse having lengths of major and minor axes of a and b, respectively;
a center of the opening is located at an origin of an orthogonal coordinate system in the plan view, and
wherein the lower pattern is determined to be within the region where the lower pattern is hidden by the upper pattern, if a following Discriminant 1 is satisfied:
$$\frac{x {1}^{2}}{{( a - c )}^{2}} + \frac{y {1}^{2}}{{( b - d )}^{2}} > 1 \qquad < Discriminant 1 >$$
when a center of gravity of the lower pattern is located at (x1, y1) in the orthogonal coordinate system.

5. The method according to claim 4, wherein the center of gravity of the lower pattern is detected on a portion of the lower pattern exposed by the opening if
$$\frac{x {1}^{2}}{{( a - c )}^{2}} + \frac{y {1}^{2}}{{( b - d )}^{2}} \leq 1.$$

6. The method according to claim 4, wherein drawing the sample pattern having the common tangential line with the lower pattern includes drawing a third ellipse that has a same shape as the second ellipse and has a common contact point with the first ellipse.

7. The method according to claim 6, wherein:
lengths of the third ellipse are a′ and b′, respectively; and
a, b, a′ and b′ satisfy a following Formula 1:
$$a / b = {a}^{′} / {b}^{′} . \qquad < Formula 1 >$$

8. The method according to claim 7, wherein:
the third ellipse and the first ellipse have the common contact point at (p, q) in the orthogonal coordinate system,
wherein the third ellipse satisfies a following Equation 1:
$$y = - \frac{{p ( {b}^{′} )}^{2}}{{q ( {a}^{′} )}^{2}} x + \frac{{( {b}^{′} )}^{2}}{q} . \qquad < Equation 1 >$$

9. The method according to claim 8, wherein the real center of gravity of the lower pattern has following coordinates in the orthogonal coordinate system,
$$( p - \frac{{m ( {c}^{2} {m}^{2} + {d}^{2} )}^{0.5}}{\frac{{d}^{2}}{{c}^{2}} + {m}^{2}} , q + \frac{\frac{{d}^{2}}{{c}^{2}} {( {c}^{2} {m}^{2} + {d}^{2} )}^{0.5}}{\frac{{d}^{2}}{{c}^{2}} + {m}^{2}} )$$
$$( m = - \frac{{p ( {b}^{′} )}^{2}}{{q ( {a}^{′} )}^{2}} ) .$$

10. The method according to claim 4, wherein the center of gravity of the lower pattern is within a region that is defined by a third ellipse having lengths of major and minor axes of (a+c) and (b+d), respectively.

11. The method according to claim 2, wherein:
a contour of the lower pattern is a circle in a plan view; and
a contour of the opening is an ellipse in the plan view.

12. The method according to claim 2, wherein:
a contour of the lower pattern is a first circle in a plan view; and
a contour of the opening is a second circle in the plan view.

13. The method according to claim 1, further comprising:
after calculating the position of the real center of gravity of the lower pattern, comparing a position of a center of the upper pattern and the calculated position of the real center of gravity of the lower pattern.

14. A method of detecting overlay of patterns, the method comprising:
forming a lower pattern and an upper pattern on a substrate;
determining whether the lower pattern is within a region where the lower pattern is hidden by the upper pattern;
drawing a sample pattern having a common contact point with the lower pattern;
determining a common tangential line of the lower pattern and the sample pattern at the common contact point;
calculating a position of a real center of gravity of the lower pattern using the common tangential line; and
comparing a position of a center of the upper pattern and the calculated position of the real center of gravity of the lower pattern.

15. The method according to claim 14, wherein the upper pattern includes an opening at least partially exposing the lower pattern.

16. The method according to claim 15, wherein:
a contour of the lower pattern is a first ellipse having lengths of major and minor axes of c and d, respectively, in a plan view;
a contour of the opening of the upper pattern is a second ellipse having lengths of major and minor axes of a and b, respectively;
a center of the opening is located at an origin of an orthogonal coordinate system in the plan view, and
wherein the lower pattern is determined to be within the region where the lower pattern is hidden by the upper pattern, if a following Discriminant 1 is satisfied:
$$\frac{x {1}^{2}}{{( a - c )}^{2}} + \frac{y {1}^{2}}{{( b - d )}^{2}} > 1 \qquad < Discriminant 1 >$$
when a center of gravity of the lower pattern is located at (x1, y1) in the orthogonal coordinate system.

17. The method according to claim 16, wherein drawing the sample pattern having the common contact point includes drawing a third ellipse having a similar shape to the second ellipse and has a common contact point with the first ellipse.

18. The method according to claim 17, wherein:
lengths of the third ellipse are a′ and b′, respectively; and
the third ellipse and the first ellipse have the common contact point at (p, q) in the orthogonal coordinate system,
wherein a, b, a′ and b′ satisfy a following Formula 1:
$$a / b = {a}^{′} / {b}^{′} ; and \qquad < Formula 1 >$$
wherein the third ellipse satisfies a following Equation 1:
$$y = - \frac{{p ( {b}^{′} )}^{2}}{{q ( {a}^{′} )}^{2}} x + \frac{{( {b}^{′} )}^{2}}{q} \qquad < Equation 1 >$$

19. The method according to claim 18, wherein the real center of gravity of the lower pattern has following coordinates in the orthogonal coordinate system,
$$( p - \frac{{m ( {c}^{2} {m}^{2} + {d}^{2} )}^{0.5}}{\frac{{d}^{2}}{{c}^{2}} + {m}^{2}} , q + \frac{\frac{{d}^{2}}{{c}^{2}} {( {c}^{2} {m}^{2} + {d}^{2} )}^{0.5}}{\frac{{d}^{2}}{{c}^{2}} + {m}^{2}} )$$
$$( m = - \frac{{p ( {b}^{′} )}^{2}}{{q ( {a}^{′} )}^{2}} ) .$$

20. A method of forming patterns, the method comprising:
forming a first lower pattern and a first upper pattern on a substrate;
drawing a sample pattern having a common tangential line with the first lower pattern;
calculating a position of a real center of gravity of the first lower pattern using the common tangential line;
comparing a position of a center of the first upper pattern and the calculated position of the real center of gravity of the first lower pattern to detect an error of overlay of the first lower pattern and the first upper pattern; and
forming a second lower pattern and a second upper pattern on the substrate by reflecting the error of overlay of the first lower pattern and the first upper pattern.
